(19) United States
(12) Patent Application Publication
(10) Pub. No.: US 2026/0229272 A1
(43) Pub. Date: Aug. 6, 2026

(54) MEMORY DEVICE PERFORMING REFRESH OPERATION AND OPERATING METHOD THEREOF

(71) Applicant: SK hynix Inc., Gyeonggi-do (KR)

(72) Inventors: Kyung Mook KIM, Gyeonggi-do (KR); Bo Yeun KIM, Gyeonggi-do (KR); Chang Ki BAEK, Gyeonggi-do (KR); Yo Sep LEE, Gyeonggi-do (KR); Yu Jin LEE, Gyeonggi-do (KR)

(21) Appl. No.: 19/248,465

(22) Filed: Jun. 25, 2025

(30) Foreign Application Priority Data
Feb. 5, 2025 (KR) 10-2025-0014324

(51) Int. Cl. G11C 11/406

(52) U.S. Cl. CPC G11C 11/40615; G11C 11/40603; G11C 11/40622

(57) ABSTRACT

A memory device includes a refresh control circuit configured to generate an internal refresh signal based on a self-refresh section signal; a locking control circuit configured to generate the self-refresh section signal according to a self-refresh entry command and a self-refresh exit command, and generate a locking start signal according to the self-refresh section signal and the internal refresh signal; and a clock generation circuit configured to generate an internal clock by delaying and fixing an external clock in response to the locking start signal.

### CROSS-REFERENCE TO RELATED APPLICATION

The present application claims priority under 35 U.S.C 119(a) to Korean Patent Application No. 10-2025-0014324, filed on Feb. 5, 2025, which is incorporated herein by reference in its entirety.

### BACKGROUND

### 1. Field

Various embodiments of the present disclosure relate to a semiconductor design technology, and more particularly, to a memory device performing a self-refresh operation.

### 2. Description of the Related Art

A memory device such as a dynamic random access memory (DRAM) may include a memory cell array for storing data. Each of the memory cells configuring the memory cell array may include a cell transistor serving as a switch and a cell capacitor storing data. To prevent loss of data stored in the cell capacitor, a refresh operation for recharging data in the memory cell is required. The refresh operation is divided into an auto-refresh operation that is performed whenever a refresh command is applied from a memory controller to the memory device, and a self-refresh operation that is performed by the memory device itself when the memory controller sets only a refresh period.

Since the memory device processes data in synchronization with an external clock, an internal clock may be generated by delaying the external clock for a certain period of time using a delay locked loop (DLL) circuit, and internal operations such as a read or write operation may be performed according to the internal clock. Since the memory device is not controlled by the internal clock during the self-refresh operation, the DLL circuit is disabled when starting the self-refresh operation, and a locking operation of the DLL circuit is performed again when ending the self-refresh operation. Therefore, a technique for adjusting a start timing of the locking operation of the DLL circuit is required.

### SUMMARY

Embodiments of the present disclosure are directed to a memory device capable of adjusting a start timing of a locking operation of a DLL circuit when exiting from a self-refresh mode, and an operating method thereof.

According to an embodiment of the present disclosure, a memory device includes a refresh control circuit configured to generate an internal refresh signal based on a self-refresh section signal; a locking control circuit configured to generate the self-refresh section signal according to a self-refresh entry command and a self-refresh exit command, and generate a locking start signal according to the self-refresh section signal and the internal refresh signal; and a clock generation circuit configured to generate an internal clock by delaying and fixing an external clock in response to the locking start signal.

According to an embodiment of the present disclosure, a memory device includes a refresh control circuit configured to generate an internal refresh signal based on a self-refresh section signal; a locking control circuit configured to generate the self-refresh section signal according to a self-refresh entry command and a self-refresh exit command, generate a first extension section signal and a second extension section signal based on the self-refresh section signal, and generate a locking start signal by selecting one of the first extension section signal and the second extension section signal based on operation speed information, the first extension section signal having a variable activation period depending on the internal refresh signal and the second extension section signal having a preset activation period; and a clock generation circuit configured to generate an internal clock by delaying and fixing an external clock in response to the locking start signal.

According to an embodiment of the present disclosure, an operating method of a memory device includes generating at least one speed signal having a logic level based on operation speed information; generating a self-refresh section signal activated by a self-refresh entry command and deactivated by a self-refresh exit command; generating an internal refresh signal during an activation period of the self-refresh section signal; generating a first extension section signal with a variable activation period depending on the internal refresh signal and a second extension section signal with a preset activation period; generating a locking start signal by selecting one of the first extension section signal and the second extension section signal according to the speed signal; and generating an internal clock by delaying and fixing an external clock in response to the locking start signal.

According to embodiments of the present disclosure, the memory device can suppress an occurrence of a peak current and prevent malfunction of a locking operation by adjusting a start timing of the locking operation of a DLL circuit not to overlap with a self-refresh operation that occurred just before exiting from a self-refresh mode.

Furthermore, according to embodiments of the present disclosure, the memory device can ensure both the stability at a high-speed operation and the efficiency at a low-speed operation by adjusting the start timing of the locking operation according to operating speed to minimize overlap with the self-refresh operation.

### BRIEF DESCRIPTION OF THE DRAWINGS

FIG. 1 is a timing diagram for describing a locking operation of a DLL circuit when exiting from a self-refresh mode.

FIG. 2 is a block diagram illustrating a memory device according to an embodiment of the present disclosure.

FIG. 3 is a detailed configuration diagram illustrating a memory core of FIG. 2.

FIGS. 4A and 4B are timing diagrams for describing bank refresh signals generated according to a first mode signal and a second mode signal of FIG. 2.

FIG. 5 is a detailed configuration diagram illustrating a self-refresh control circuit of FIG. 2.

FIG. 6 is a detailed circuit diagram illustrating a first signal generator of FIG. 5.

FIG. 7 is a detailed circuit diagram illustrating a second signal generator of FIG. 5.

FIGS. 8A and 8B are timing diagrams for describing an operation of the self-refresh control circuit of FIG. 5.

FIG. 9 is a detailed configuration diagram illustrating a start control circuit of FIG. 2.

FIG. 10 is a block diagram illustrating a memory device according to another embodiment of the present disclosure.

FIG. 11 is a detailed circuit diagram illustrating a start control circuit of FIG. 10.

FIG. 12 is a table for describing an operation of the start control circuit of FIG. 11.

FIGS. 13A and 13B are timing diagrams for describing an operation of the memory device of FIG. 10.

FIG. 14 is a block diagram illustrating a memory system according to an embodiment of the present disclosure.

### DETAILED DESCRIPTION

Various embodiments of the present disclosure will be described below in more detail with reference to the accompanying drawings. The embodiments of the present disclosure may, however, be embodied in different forms and should not be construed as limited to the embodiments set forth herein. Rather, these embodiments are provided so that this disclosure will be thorough and complete, and will fully convey the scope of the present disclosure to those skilled in the art. Throughout this disclosure, like reference numerals refer to like parts throughout the various figures and embodiments of the present disclosure.

It will be understood that when an element is referred to as being “coupled” or “connected” to another element, it may mean that the two are directly coupled or the two are electrically connected to each other with another circuit intervening therebetween. It will be further understood that the terms “comprise”, “include”, “have”, etc. when used in this specification, specify the presence of stated features, numbers, steps, operations, elements, components, and/or combinations of them but do not preclude the presence or addition of one or more other features, numbers, steps, operations, elements, components, and/or combinations thereof. In the present disclosure, the singular forms are intended to include the plural forms as well, unless the context clearly indicates otherwise.

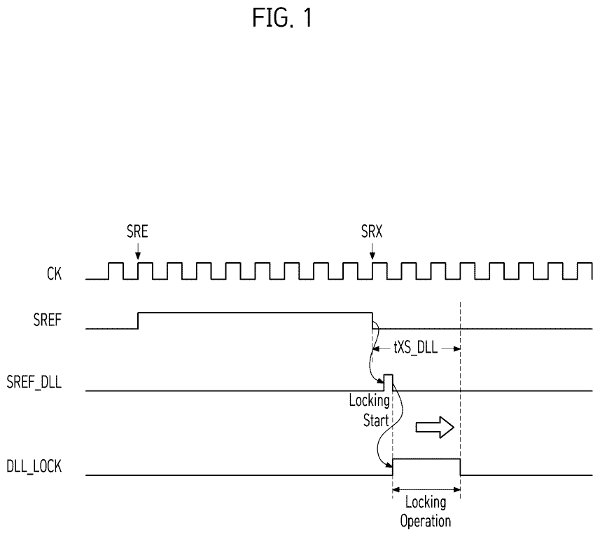

FIG. 1 is a timing diagram for describing a locking operation of a DLL circuit when exiting from a self-refresh mode.

Referring to FIG. 1, a memory device may receive a self-refresh entry command SRE and a self-refresh exit command SRX in synchronization with an external clock CK from an external device (e.g., a memory controller), and generate a self-refresh section signal SREF whose activation period is defined by the commands. The memory device may generate a predetermined number of internal refresh signals during the activation period of the self-refresh section signal SREF, and perform a self-refresh operation that sequentially refreshes a plurality of rows in response to the internal refresh signals.

The memory device may receive a valid command after a predetermined time (hereinafter referred to as “tXS_DLL”) has elapsed from the input of the self-refresh exit command SRX, as defined in the specification (e.g., JEDEC specification for double data rate (DDR) type or low-power DDR (LPDDR) type DRAM for timing parameters). The valid command may be for instructing an operation synchronized with the external clock CK. Accordingly, the memory device may control a delay-locked loop (DLL) circuit so that a locking operation is completed within the predetermined time tXS_DLL. For example, the memory device may generate a locking start signal SREF_DLL in response to the self-refresh exit command SRX, and the DLL circuit may initiate a locking operation in response to the locking start signal SREF_DLL. In FIG. 1, a signal labeled “DLL_LOCK” denotes a signal that is activated while the locking operation is being performed.

At this time, if the self-refresh operation according to an internal refresh signal generated just before exiting from a self-refresh mode, overlaps with the locking operation of the DLL circuit, the peak current consumption may increase, thereby generating power noise. In particular, the DLL circuit included to generate an internal clock of the memory device is a sensitive circuit comprising long delay lines, and when the supplied voltage is unstable, timing errors may occur, which may result in malfunction of the memory device. Accordingly, various methods for controlling the timing of initiating the locking operation have been discussed to reduce the overlap between the self-refresh operation and the locking operation.

Hereinafter, the present disclosure will describe methods of adjusting an activation timing of the locking start signal SREF_DLL to minimize overlap between the self-refresh operation that occurs immediately before exiting from the self-refresh mode and the locking operation of the DLL circuit.

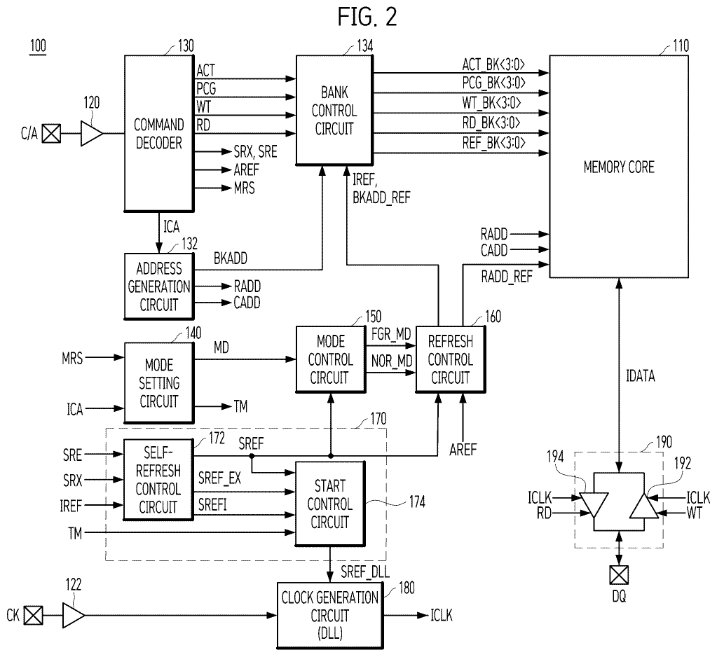

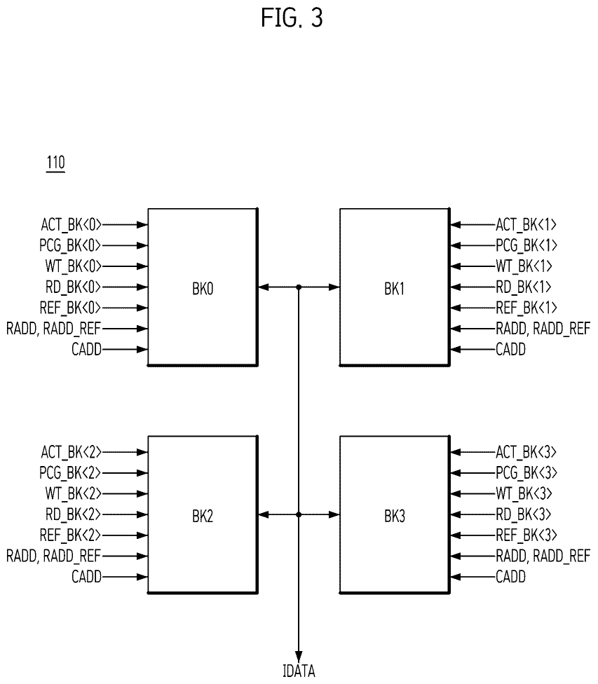

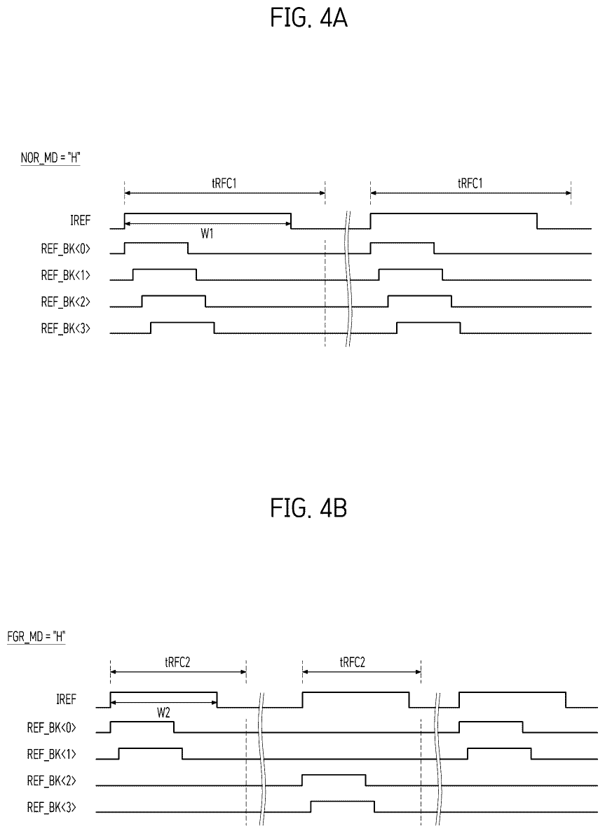

FIG. 2 is a block diagram illustrating a memory device 100 according to an embodiment of the present disclosure. FIG. 3 is a detailed configuration diagram illustrating a memory core 110 of FIG. 2. FIGS. 4A and 4B are timing diagrams for describing bank refresh signals REF_BK<3:0> generated according to a first mode signal NOR_MD and a second mode signal FGR_MD of FIG. 2.

Referring to FIG. 2, the memory device 100 may include a memory core 110, a command/address receiving circuit 120, a clock buffer 122, a command decoder 130, an address generation circuit 132, a bank control circuit 134, a mode setting circuit 140, a mode control circuit 150, a refresh control circuit 160, a locking control circuit 170, a clock generation circuit 180, and a data input/output circuit 190.

The memory core 110 may be a region where data is stored in the memory device 100. As shown in FIG. 3, the memory core 110 may include first to fourth banks BK0 to BK3. Each of the first to fourth banks BK0 to BK3 may include a cell array region in which a plurality of memory cells coupled to a plurality of rows and a plurality of columns are arranged in an array type, and a peripheral circuit configured to perform active, precharge, read, write, and refresh operations on the cell array region. The peripheral circuit may include a row decoder configured to activate or deactivate the rows of the cell array region, and a column decoder and an I/O circuit configured to input/output data from the cell array region.

Each of the first to fourth banks BK0 to BK3 may perform an activate operation to activate a row selected by a row address RADD when a corresponding bank active signal among bank active signals ACT_BK<0:3> is activated. Each of the first to fourth banks BK0 to BK3 may perform a precharge operation to deactivate the activated row when a corresponding bank precharge signal among bank precharge signals PCG_BK<0:3> is activated. Each of the first to fourth banks BK0 to BK3 may perform a write operation to write data IDATA to memory cells coupled to columns selected by a column address CADD when a corresponding bank write signal among bank write signals WT_BK<0:3> is activated. Each of the first to fourth banks BK0 to BK3 may perform a read operation to read data IDATA from memory cells coupled to columns selected by the column address CADD when a corresponding bank read signal among bank read signals RD_BK<0:3> is activated. Further, each of the first to fourth banks BK0 to BK3 may perform a refresh operation to refresh a row selected by a row refresh address RADD_REF when a corresponding bank refresh signal among bank refresh signals REF_BK<3:0> is activated.

The command/address receiving circuit 120 may receive a command/address signal C/A. Depending on a type of memory device 100, a command and an address may be input through the same input terminals, or a command and an address may be input through separate input terminals, where it is illustrated that a command and an address are input through the same input terminals. The command/address signal C/A may be composed of multiple bits.

The clock buffer 122 may receive an external clock CK from a memory controller. The command/address receiving circuit 120 may receive the command/address signal C/A in synchronization with a clock received by the clock buffer 122.

The command decoder 130 may decode the command/address signal C/A received by the command/address receiving circuit 120 to generate an active command ACT, a precharge command PCG, a write command WT, a read command RD, a self-refresh entry command SRE, a self-refresh exit command SRX, an auto-refresh command AREF, and a mode setting command MRS.

The active command ACT is a signal input when an active operation is indicated, the precharge command PCG is a signal input when a precharge operation is indicated, the write command WT is a signal input when a write operation is indicated, and the read command RD may be a signal input when a read operation is indicated. The self-refresh entry command SRE and the self-refresh exit command SRX are signals to define a refresh period for performing a self-refresh operation. A self-refresh section signal SREF, which will be described below, may be a signal having an activation period determined by the self-refresh entry command SRE and the self-refresh exit command SRX. The activation period of the self-refresh section signal SREF may be defined as a self-refresh operation section. The auto-refresh command AREF is a signal provided by the memory controller to indicate an auto-refresh operation. For reference, a refresh operation may include an auto-refresh operation executed each time a refresh command is applied from the memory controller to the memory device, and a self-refresh operation autonomously performed by the memory device when the memory controller only defines the refresh period. The mode setting command MRS is a signal for reading configuration data corresponding to an internal address signal ICA, from the mode setting circuit 140.

The address generation circuit 132 may classify the internal address signal ICA received from the command decoder 160 into a bank address BKADD, the row address RADD, and the column address CADD. The bank address BKADD is used to select one of the first to fourth banks BK0 to BK3 included in the memory core 110. The row address RADD is used to select one of the rows within a bank. The column address CADD is used to select columns for read and write operations within a bank. Each of the addresses BKADD, RADD, and CADD may be composed of multiple bits.

The bank control circuit 134 may decode the bank address BKADD to generate the bank activate signals ACT_BK<3:0>, the bank precharge signals PCG_BK<3:0>, the bank read signals RD_BK<3:0>, and the bank write signals WT_BK<3:0> corresponding to the first to fourth banks BK0 to BK3, respectively. The bank control circuit 134 may activate a bank activate signal of a bank selected by the bank address BKADD, among the bank activate signals ACT_BK<3:0>, in response to the active command ACT. Similarly, the bank control circuit 134 may activate a bank precharge signal of a bank selected by the bank address BKADD, among the bank precharge signals PCG_BK<3:0>, in response to the precharge command PCG, activate a bank write signal of a bank selected by the bank address BKADD, among the bank write signals WT_BK<3:0>, in response to the write command WT, and activate a bank read signal of a bank selected by the bank address BKADD, among the bank read signals RD_BK<3:0>, in response to the read command RD. The bank control circuit 134 may also decode a bank refresh address BKADD_REF to generate the bank refresh signals REF_BK<3:0> corresponding to the first to fourth banks BK0 to BK3, respectively. The bank control circuit 134 may activate a bank refresh signal for a bank selected by the bank refresh address BKADD_REF, among the bank refresh signals REF_BK<3:0>, in response to an internal refresh signal IREF.

The mode setting circuit 140 may store the configuration data for internal operations, and read out the configuration data corresponding to the internal address signal ICA in response to the mode setting command MRS. The mode setting circuit 140 may be implemented with a known mode register set. In an embodiment, the configuration data may include refresh setting information MD for setting a refresh operation mode and test mode information TM for setting locking operation parameters.

The mode control circuit 150 may output one of a first mode signal NOR_MD and a second mode signal FGR_MD based on the self-refresh section signal SREF and the refresh setting information MD. The mode control circuit 150 may output the first mode signal NOR_MD or the second mode signal FGR_MD depending on the refresh setting information MD, while outputting the second mode signal FGR_MD, regardless of the refresh setting information MD, during the activation period of the self-refresh section signal SREF (i.e., the self-refresh operation section). The second mode signal FGR_MD may be a signal indicating a Fine Granularity Refresh (FGR) mode, and the first mode signal NOR_MD may be a signal indicating a mode (hereinafter, referred to as a normal mode), other than the FGR mode.

For reference, the FGR mode divides a refresh operation into finer granularity, such that a refresh operation that would normally be performed in a single refresh command within one refresh cycle (tRFC) is instead divided and executed over two or four refresh commands. In an embodiment, the mode control circuit 150 may output either the first mode signal NOR_MD or the second mode signal FGR_MD depending on a mode setting but may output, during the self-refresh operation, the second mode signal FGR_MD regardless of the mode setting.

The refresh control circuit 160 may generate the internal refresh signal IREF in response to the self-refresh section signal SREF and the auto-refresh command AREF. During the activation period of the self-refresh section signal SREF, the refresh control circuit 160 may periodically activate the internal refresh signal IREF, thereby performing a self-refresh operation that sequentially refreshes the plurality of rows during the self-refresh operation. Additionally, the refresh control circuit 160 may activate the internal refresh signal IREF each time the auto-refresh command AREF is input. Accordingly, an auto-refresh operation may be performed to sequentially refresh the plurality of rows each time the auto-refresh command AREF is input.

Further, the refresh control circuit 160 may adjust the number and/or pulse width of the internal refresh signal IREF based on the first mode signal NOR_MD and the second mode signal FGR_MD. Based on the first mode signal NOR_MD, the second mode signal FGR_MD, and the internal refresh signal IREF, the refresh control circuit 160 may generate the bank refresh address BKADD_REF and the row refresh address RADD_REF to designate a row in a bank to be refreshed. In some embodiments, the refresh control circuit 160 may separately generate the bank refresh address BKADD_REF and the row refresh address RADD_REF for the auto-refresh operation and the self-refresh operation.

Referring to FIG. 4A, the bank refresh signals REF_BK<3:0> which are generated during a first mode in which the first mode signal NOR_MD is activated (NOR_MD=“H”), are illustrated. In the first mode, the refresh control circuit 160 may control the internal refresh signal IREF to pulse with a first pulse width W1 during a first unit refresh cycle tRFC1 and sequentially output the bank refresh address BKADD_REF with values from 0 to 3. At this time, the refresh control circuit 160 may change the row refresh address RADD_REF (e.g., increment by “+1”) whenever the internal refresh signal IREF is activated once. Accordingly, during the first unit refresh cycle tRFC1, the bank refresh signals REF_BK<3:0> may be sequentially activated to refresh one row in each of the first to fourth banks BK0 to BK3.

Referring to FIG. 4B, the bank refresh signals REF_BK<3:0> which are generated during a second mode in which the second mode signal FGR_MD is activated (FGR_MD=“H”), are illustrated. In the second mode, the refresh control circuit 160 may control the internal refresh signal IREF to pulse with a second pulse width W2 during a second unit refresh cycle tRFC2 and may change, from 0 to 1 or from 2 to 3, the value of the bank refresh address BKADD_REF to output the bank refresh address BKADD_REF of the changed value. At this time, the refresh control circuit 160 may change the row refresh address RADD_REF whenever the internal refresh signal IREF is activated twice. Accordingly, during the second unit refresh cycle tRFC2, two of the bank refresh signals REF_BK<3:0> may be sequentially activated to refresh one row in each of two banks among BK0 to BK3.

As shown in FIGS. 4A and 4B, in the first mode, all banks BK0 to BK3 may be refreshed according to one internal refresh signal IREF, and in the second mode, all banks may be refreshed according to two internal refresh signals IREF. Accordingly, the first unit refresh cycle tRFC1 may be relatively longer than the second unit refresh cycle tRFC2, and the first pulse width W1 of the internal refresh signal IREF in the first mode may be relatively greater than the second pulse width W2 in the second mode. Although FIGS. 4A and 4B illustrate that the bank refresh signals REF_BK<3:0> are sequentially activated to reduce peak current, the bank refresh signals REF_BK<3:0> may be activated simultaneously depending on an embodiment.

The locking control circuit 170 may generate the self-refresh section signal SREF based on the self-refresh entry command SRE and the self-refresh exit command SRX, and generate a locking start signal SREF_DLL based on the self-refresh section signal SREF and the internal refresh signal IREF.

More specifically, the locking control circuit 170 may include a self-refresh control circuit 172 and a start control circuit 174.

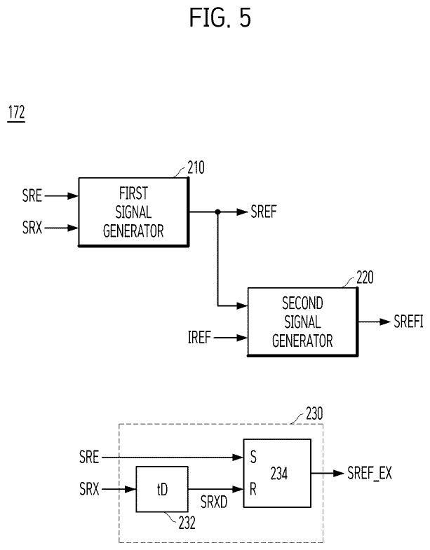

The self-refresh control circuit 172 may generate the self-refresh section signal SREF based on the self-refresh entry command SRE and the self-refresh exit command SRX. The self-refresh control circuit 172 may generate a first extension section signal SREFI and a second extension section signal SREF_EX based on the self-refresh section signal SREF. The self-refresh control circuit 172 may control the first extension section signal SREFI to have a variable activation period depending on the internal refresh signal IREF, and may control the second extension section signal SREF_EX to have a preset activation period. The detailed configuration and operation of the self-refresh control circuit 172 will be described with reference to FIGS. 5 to 8B.

The start control circuit 174 may output the locking start signal SREF_DLL by selecting one of the first extension section signal SREFI and the second extension section signal SREF_EX in response to the test mode information TM provided from the mode setting circuit 140. In some embodiments, the start control circuit 174 may output the locking start signal SREF_DLL by selecting one of the self-refresh section signal SREF, the first extension section signal SREFI, and the second extension section signal SREF_EX in response to the test mode information TM.

The clock generation circuit 180 may generate an internal clock ICLK based on the clock received by the clock buffer 122. The clock generation circuit 180 may be disabled according to a reset signal (not shown) in a power-down mode and may be enabled according to the locking start signal SREF_DLL. For example, the clock generation circuit 180 may be implemented with a known delay locked loop (DLL) circuit. The DLL circuit may generate the internal clock ICLK by performing a locking operation to delay and fix a phase of the clock received by the clock buffer 122 in response to the locking start signal SREF_DLL.

The data input/output circuit 190 may receive data DQ from the memory controller or transmit the data DQ to the memory controller. The data input/output circuit 190 may transmit and receive the data DQ in synchronization with the internal clock ICLK. The data input/output circuit 190 may include a data input circuit 192 that receives the data DQ to be written to the memory core 110 during a write operation, and a data output circuit 194 that transmits the data DQ read from the memory core 110 during a read operation. The data input circuit 192 may receive the data DQ in synchronization with the internal clock ICLK according to a write command WT, and the data output circuit 194 may transmit the data DQ in synchronization with the internal clock ICLK according to a read command RD.

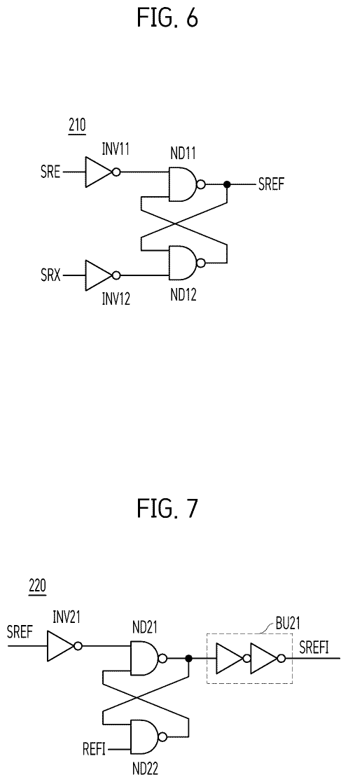

FIG. 5 is a detailed configuration diagram illustrating the self-refresh control circuit 172 of FIG. 2. FIG. 6 is a detailed circuit diagram illustrating a first signal generator 210 of FIG. 5. FIG. 7 is a detailed circuit diagram illustrating a second signal generator 220 of FIG. 5.

Referring to FIG. 5, the self-refresh control circuit 172 may include first to third signal generators 210 to 230.

The first signal generator 210 may generate the self-refresh section signal SREF that is activated in response to the self-refresh entry command SRE and deactivated in response to the self-refresh exit command SRX. For example, referring to FIG. 6, the first signal generator 210 may include a first inverter INV11, a second inverter INV12, a first NAND gate ND11, and a second NAND gate ND12, to be implemented as an SR latch that receives the self-refresh entry command SRE as a set signal and the self-refresh exit command SRX as a reset signal.

The second signal generator 220 may generate the first extension section signal SREFI that is activated in response to the self-refresh entry command SRE and deactivated in response to the self-refresh exit command SRX or the internal refresh signal IREF. For example, referring to FIG. 7, the second signal generator 220 may include a first inverter INV21, a first NAND gate ND21, a second NAND gate ND22, and a buffer BU21. The first inverter INV21 may invert the self-refresh section signal SREF. The first NAND gate ND21 whose output terminal is cross-coupled to an input terminal of the second NAND gate ND22, may receive an output signal of the first inverter INV21 at another input. The second NAND gate ND22 whose output terminal is cross-coupled to an input terminal of the first NAND gate ND21, may receive the internal refresh signal IREF at another input. The buffer BU21 may buffer an output signal of the first NAND gate ND21 to output the first extension section signal SREFI. The buffer BU21 may be implemented with a chain of an even number of inverters. With this configuration, the second signal generator 220 may generate the first extension section signal SREFI, which is activated when the self-refresh section signal SREF is activated and deactivated when the self-refresh section signal SREF is deactivated. Here, the first extension section signal SREFI may have an activation period variable depending on whether the internal refresh signal IREF is activated at deactivation of the self-refresh section signal SREF.

The third signal generator 230 may generate the second extension section signal SREF_EX, which is activated in response to the self-refresh entry command SRE and deactivated in response to a delayed signal SRXD that is the self-refresh exit command SRX delayed by a preset delay time tD. For example, the third signal generator 230 may include a delay circuit 232 and an SR latch 234. The delay circuit 232 may generate the delayed signal SRXD by delaying the self-refresh exit command SRX by the preset delay time tD. The SR latch 234 may receive the self-refresh entry command SRE as a set signal and the delayed signal SRXD as a reset signal. The delay circuit 232 may be implemented with an RC delay. The SR latch 234 may have substantially the same configuration as the first signal generator 210 shown in FIG. 6. With this configuration, the third signal generator 230 may generate the second extension section signal SREF_EX that has an activation period extended by a fixed delay time tD from an end of the self-refresh operation section.

The preset delay time tD of the third signal generator 230 may be set to a time shorter than the pulse width of the internal refresh signal IREF in the second mode, i.e., the second pulse width W2. For example, when the second pulse width W2 is set to 60 ns, the preset delay time tD may be set to 30 to 50 ns.

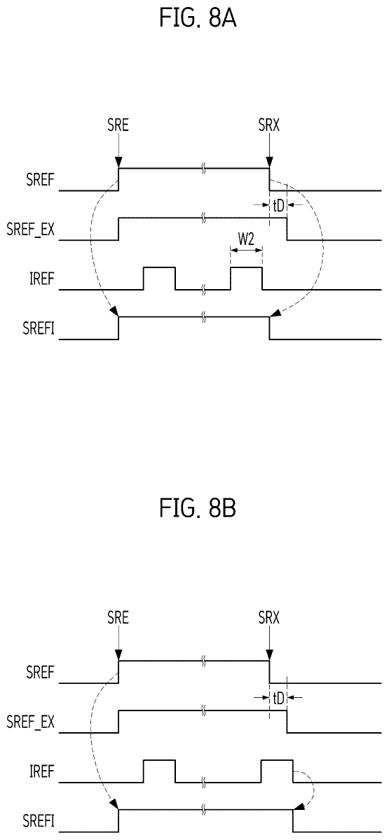

FIGS. 8A and 8B are timing diagrams for describing an operation of the self-refresh control circuit 172 of FIG. 5.

Referring to FIGS. 8A and 8B, the first signal generator 210 may generate the self-refresh section signal SREF that is activated in response to the self-refresh entry command SRE and deactivated in response to the self-refresh exit command SRX. In an embodiment, during the activation period of the self-refresh section signal SREF (i.e., during the self-refresh operation), the second mode signal FGR_MD may be activated regardless of the refresh setting information MD, and the internal refresh signal IREF may pulse with the second pulse width W2.

The third signal generator 230 may generate the second extension section signal SREF_EX that is activated in response to the self-refresh entry command SRE and deactivated after the preset delay time tD from the activation of the self-refresh exit command SRX. At this time, the preset delay time tD may be set to a time shorter than the pulse width (i.e., the second pulse width W2) of the internal refresh signal IREF in the second mode.

The second signal generator 220 may generate the first extension section signal SREFI that is activated in response to the self-refresh entry command SRE and deactivated in response to the self-refresh exit command SRX or the internal refresh signal IREF.

As shown in FIG. 8A, when the internal refresh signal IREF is deactivated at the time of deactivation of the self-refresh section signal SREF, the second signal generator 220 may generate the first extension section signal SREFI that is deactivated in response to the self-refresh exit command SRX. In this case, the first extension section signal SREFI may have the same activation period as the self-refresh section signal SREF, and the second extension section signal SREF_EX, among the self-refresh section signal SREF, the first extension section signal SREFI, and the second extension section signal SREF_EX, may have the longest activation period.

On the other hand, as shown in FIG. 8B, when the internal refresh signal IREF is activated at the time of deactivation of the self-refresh section signal SREF, that is, when the internal refresh signal IREF is generated just before exiting from the self-refresh mode, the second signal generator 220 may generate the first extension section signal SREFI that is deactivated at a falling edge of the internal refresh signal IREF. In this case, the first extension section signal SREFI may have a more extended activation period than the self-refresh section signal SREF due to the internal refresh signal IREF, and the first extension section signal SREFI may have the longest activation period among the self-refresh section signal SREF, the first extension section signal SREFI, and the second extension section signal SREF_EX.

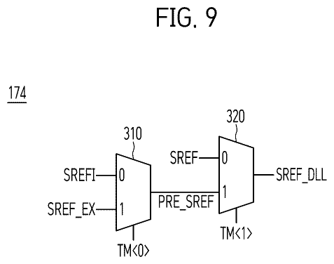

FIG. 9 is a detailed configuration diagram illustrating the start control circuit 174 of FIG. 2.

Referring to FIG. 9, the start control circuit 174 may include a first multiplexer 310 and a second multiplexer 320.

The first multiplexer 310 may output a pre-extension section signal PRE_SREF by selecting one of the first extension section signal SREFI and the second extension section signal SREF_EX in response to a first bit TM<0> of the test mode information TM<1:0>. The first bit TM<0> may be referred to as a first test mode signal. For example, the first multiplexer 310 may select the first extension section signal SREFI when the first test mode signal TM<0> is a logic low level, and select the second extension section signal SREF_EX when the first test mode signal TM<0> is a logic high level.

The second multiplexer 320 may output the locking start signal SREF_DLL by selecting one of the self-refresh section signal SREF and the pre-extension section signal PRE_SREF in response to a second bit TM<1> of the test mode information TM<1:0>. The second bit TM<1> may be referred to as a second test mode signal. For example, the second multiplexer 320 may select the self-refresh section signal SREF when the second test mode signal TM<1> is a logic low level, and select the pre-extension section signal PRE_SREF when the second test mode signal TM<1> is a logic high level.

With the above configuration, the start control circuit 174 may select one of the self-refresh section signal SREF, the first extension section signal SREFI, and the second extension section signal SREF_EX in response to the test mode information TM, and output the selected signal as the locking start signal SREF_DLL.

As described above, the memory device 100 according to an embodiment of the present disclosure may adjust the activation timing of the locking start signal SREF_DLL so that the locking operation of the DLL circuit does not overlap with the self-refresh operation occurring just before exiting from the self-refresh mode. For example, the memory device 100 may, in response to test mode information TM<1:0> of “10,” generate the locking start signal SREF_DLL based on the first extension section signal SREFI, thereby controlling the DLL circuit to perform the locking operation after the self-refresh operation is completed, and thus prevent the overlap between the self-refresh operation and the locking operation. Alternatively, in response to test mode information TM of “11,” the memory device 100 may generate the locking start signal SREF_DLL based on the second extension section signal SREF_EX, thereby minimizing the overlap between the self-refresh operation and the locking operation while ensuring the flexibility. Accordingly, the occurrence of peak current may be suppressed, and malfunction of the locking operation may be prevented.

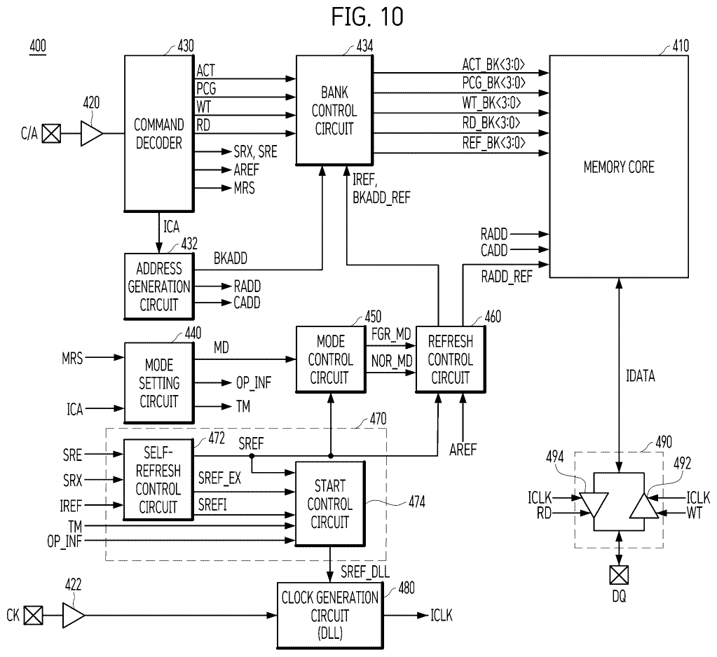

FIG. 10 is a block diagram illustrating a memory device 400 according to another embodiment of the present disclosure.

Referring to FIG. 10, the memory device 400 may include a memory core 410, a command/address receiving circuit 420, a clock buffer 422, a command decoder 430, an address generation circuit 432, a bank control circuit 434, a mode setting circuit 440, a mode control circuit 450, a refresh control circuit 460, a locking control circuit 470, a clock generation circuit 480, and a data input/output circuit 490.

The memory core 410, the command/address receiving circuit 420, the clock buffer 422, the command decoder 430, the address generation circuit 432, the bank control circuit 434, the mode control circuit 450, the refresh control circuit 460, the clock generation circuit 480, and the data input/output circuit 490 of FIG. 10 may perform substantially the same configurations and operations as those of the components shown in FIG. 2.

The mode setting circuit 440 may store configuration data for setting internal operations, and read out the configuration data corresponding to an internal address signal ICA in response to a mode setting command MRS. The configuration data may include refresh setting information MD for setting a refresh operation mode, test mode information TM for setting locking operation parameters, and operation speed information OP_INF for indicating a data transfer rate of the memory device 400.

The locking control circuit 470 may generate a self-refresh section signal SREF in response to a self-refresh entry command SRE and a self-refresh exit command SRX, and generate a first extension section signal SREFI and a second extension section signal SREF_EX based on the self-refresh section signal SREF. The locking control circuit 470 may control the first extension section signal SREFI to have a variable activation period depending on an internal refresh signal IREF, and may control the second extension section signal SREF_EX to have a preset activation period. The locking control circuit 470 may generate a locking start signal SREF_DLL by selecting one of the first extension section signal SREFI and the second extension section signal SREF_EX according to the operation speed information OP_INF.

More specifically, the locking control circuit 470 may include a self-refresh control circuit 472 and a start control circuit 474.

The self-refresh control circuit 472 may generate the self-refresh section signal SREF in response to the self-refresh entry command SRE and the self-refresh exit command SRX. The self-refresh control circuit 472 may generate the first extension section signal SREFI and the second extension section signal SREF_EX based on the self-refresh section signal SREF. The self-refresh control circuit 472 may perform substantially the same configuration and operation as the self-refresh control circuit 172 described in FIGS. 5 to 8B.

The start control circuit 474 may output the locking start signal SREF_DLL by selecting one of the first extension section signal SREFI and the second extension section signal SREF_EX in response to the test mode information TM and the operation speed information OP_INF provided from the mode setting circuit 440. In some embodiments, the start control circuit 474 may output the locking start signal SREF_DLL by selecting one of the self-refresh section signal SREF, the first extension section signal SREFI, and the second extension section signal SREF_EX in response to the test mode information TM and the operation speed information OP_INF.

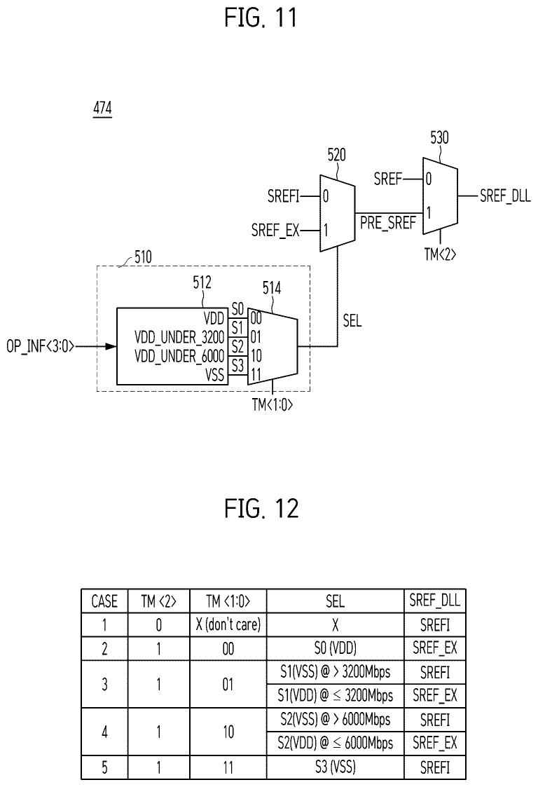

FIG. 11 is a detailed circuit diagram illustrating the start control circuit 474 of FIG. 10.

Referring to FIG. 11, the start control circuit 474 may include a selection control circuit 510, a first multiplexer 520, and a second multiplexer 530.

The selection control circuit 510 may set first to fourth speed signals S0 to S3 according to the operation speed information OP_INF<3:0>, and output a selection signal SEL by selecting one of the speed signals S0 to S3 in response to first and second bits TM<0> and TM<1> of the test mode information TM<2:0>. The first and second bits TM<1:0> may be referred to as a first test mode signal.

The first multiplexer 520 may output a pre-extension section signal PRE_SREF by selecting one of the first extension section signal SREFI and the second extension section signal SREF_EX in response to the selection signal SEL. For example, the first multiplexer 520 may select the first extension section signal SREFI when the selection signal SEL is a logic low level, and select the second extension section signal SREF_EX when the selection signal SEL is a logic high level.

The second multiplexer 530 may output the locking start signal SREF_DLL by selecting one of the self-refresh section signal SREF and the pre-extension section signal PRE_SREF in response to a third bit TM<2> of the test mode information TM<2:0>. The third bit TM<2> may be referred to as a second test mode signal. For example, the second multiplexer 530 may select the self-refresh section signal SREF when the second test mode signal TM<2> is a logic low level, and select the pre-extension section signal PRE_SREF when the second test mode signal TM<2> is a logic high level.

More specifically, the selection control circuit 510 may include a speed setting circuit 512 and a third multiplexer 514.

The speed setting circuit 512 may set the first to fourth speed signals S0 to S3 according to the operation speed information OP_INF<3:0>. In this case, the first speed signal S0 may be fixed to a logic high level and the fourth speed signal S3 may be fixed to a logic low level, while the second speed signal S1 and the third speed signal S2 may have logic levels that vary according to the operation speed information OP_INF<3:0>. For example, the second speed signal S1 may be a logic high level when the data rate of the memory device 400 is set to 3200 Mbps or less, and a logic low level when the data rate exceeds 3200 Mbps. The third speed signal S2 may be a logic high level when the data rate of the memory device 400 is set to 6000 Mbps or less, and a logic low level when the data rate exceeds 6000 Mbps.

The third multiplexer 514 may output the selection signal SEL by selecting one of the first to fourth speed signals S0 to S3 in response to the first test mode signal TM<1:0>.

For example, the third multiplexer 514 may output the first speed signal S0, which is a logic high level, as the selection signal SEL, in response to the first test mode signal TM<1:0> of “00”, and may output the fourth speed signal S3, which is a logic low level, as the selection signal SEL, in response to the first test mode signal TM<1:0> of “11”. The third multiplexer 514 may output the second speed signal S1 as the selection signal SEL in response to the first test mode signal TM<1:0> of “01”, and may output the third speed signal S2 as the selection signal SEL in response to the first test mode signal TM<1:0> of “10”.

FIG. 12 is a table for describing an operation of the start control circuit 474 of FIG. 11.

Referring to FIG. 12, when the second test mode signal TM<2> is a logic low level (CASE I), the start control circuit 474 may output the self-refresh section signal SREF as the locking start signal SREF_DLL, regardless of the selection signal SEL, i.e., the test mode information TM<2:0>.

When the test mode information TM<2:0> of “100” is input (CASE 2), the start control circuit 474 may output the first speed signal S0 set to a logic high level as the selection signal SEL, and in response to the selection signal SEL, may output the second extension section signal SREF_EX as the locking start signal SREF_DLL.

When the test mode information TM<2:0> of “101” is input (CASE 3), the start control circuit 474 may output the second speed signal S1 as the selection signal SEL, and may output either the first extension section signal SREFI or the second extension section signal SREF_EX as the locking start signal SREF_DLL in response to the selection signal SEL. In this case, when the operation speed information OP_INF<3:0> indicates a data rate greater than 3200 Mbps, the start control circuit 474 may output the first extension section signal SREFI. When the operation speed information OP_INF<3:0> indicates a data rate less than or equal to 3200 Mbps, the start control circuit 474 may output the second extension section signal SREF_EX. That is, in an environment of 3200 Mbps or less, the locking operation is controlled by the second extension section signal SREF_EX, and in an environment exceeding 3200 Mbps, the locking operation is controlled by the first extension section signal SREFI.

When the test mode information TM<2:0> of “110” is input (CASE 4), the start control circuit 474 may output the third speed signal S2 as the selection signal SEL, and may output either the first extension section signal SREFI or the second extension section signal SREF_EX as the locking start signal SREF_DLL in response to the selection signal SEL. In this case, when the operation speed information OP_INF<3:0> indicates a data rate greater than 6000 Mbps, the start control circuit 474 may output the first extension section signal SREFI. When the operation speed information OP_INF<3:0> indicates a data rate less than or equal to 6000 Mbps, the start control circuit 474 may output the second extension section signal SREF_EX. That is, in an environment of 6000 Mbps or less, the locking operation is controlled by the second extension section signal SREF_EX, and in an environment exceeding 6000 Mbps, the locking operation is controlled by the first extension section signal SREFI.

When the test mode information TM<2:0> of “111” is input (CASE 5), the start control circuit 474 may output the fourth speed signal S3 set to a logic low level as the selection signal SEL, and may output the first extension section signal SREFI as the locking start signal SREF_DLL in response to the selection signal SEL.

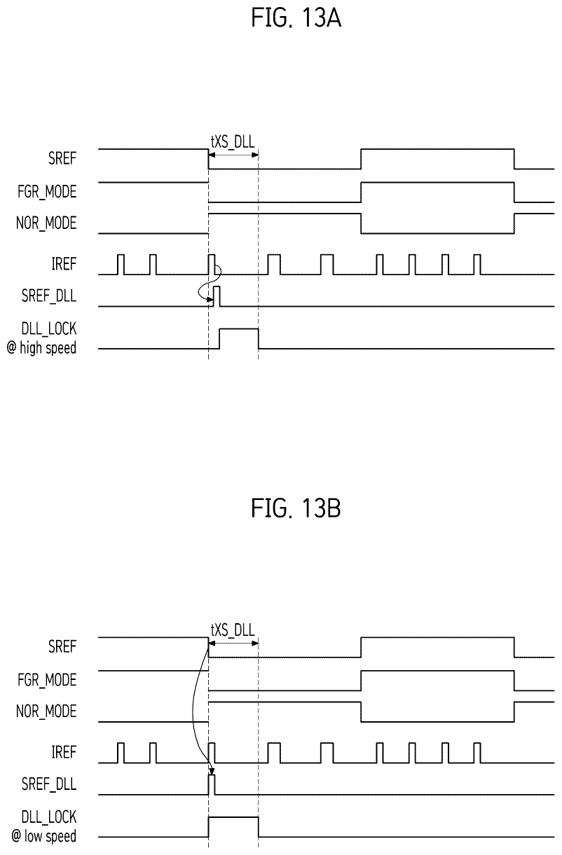

FIGS. 13A and 13B are timing diagrams for describing an operation of the memory device 400 of FIG. 10.

Referring to FIGS. 13A and 13B, the self-refresh section signal SREF may be activated in response to the self-refresh entry command SRE and deactivated in response to the self-refresh exit command SRX. During the activation period of the self-refresh section signal SREF, i.e., during the self-refresh operation, the first mode signal NOR_MD may be deactivated and the second mode signal FGR_MD may be activated so that the FGR mode is applied.

Referring to FIG. 13A, the memory device 400 operating at speed higher than a reference speed (e.g., above 3200 Mbps or 6000 Mbps) may generate the first extension section signal SREFI based on the internal refresh signal IREF that occurs immediately before exiting from the self-refresh mode, and may generate the locking start signal SREF_DLL based on the first extension section signal SREFI. As a result, the memory device 400 operating at the higher speed may adjust the timing of the locking operation to activate the locking start signal SREF_DLL at a falling edge of the internal refresh signal IREF, thereby preventing overlap between the self-refresh operation and the locking operation.

Referring to FIG. 13B, the memory device 400 operating at speed lower than the reference speed may generate the locking start signal SREF_DLL based on the second extension section signal SREF_EX, which has a preset activation period, regardless of the internal refresh signal IREF occurring immediately before the end of the self-refresh operation. As a result, the memory device 400 operating at the lower speed may activate the locking start signal SREF_DLL with a fixed margin from the end of the self-refresh operation, thereby minimizing the overlap while ensuring that the locking operation is completed within the predetermined time tXS_DLL defined in the specification.

As described above, the memory device 400 according to an embodiment of the present disclosure may flexibly adjust the activation timing of the locking start signal SREF_DLL based on the operating speed, such that the overlap between the self-refresh operation and the locking operation of the DLL circuit is minimized. Accordingly, both the stability in high-speed operation and the efficiency in low-speed operation can be ensured.

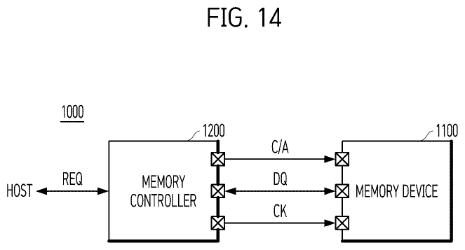

FIG. 14 is a block diagram illustrating a memory system 1000 according to an embodiment of the present disclosure.

Referring to FIG. 14, the memory system 1000 may include a memory device 1100 and a memory controller 1200.

The memory system 1000 is a device that stores data under the control of a host, such as a mobile phone, smartphone, MP3 player, laptop computer, desktop computer, game console, TV, tablet PC, or in-vehicle infotainment system. The host may be an external device of the memory system 1000.

The memory controller 1200 generally controls the operation of the memory system 1000 and controls overall data exchange between the host and the memory device 1100. The memory controller 1200 may generate a command/address signal C/A in response to a request REQ from the host and provide it to the memory device 1100. The memory controller 1200 may also provide a clock CK along with the command/address signal C/A. The memory controller 1200 may provide data DQ corresponding to the request REQ from the host to the memory device 1100, and may provide the data DQ read from the memory device 1100 to the host. The command/address signal C/A provided from the memory controller 1200 to the memory device 1100 may include an active command, a precharge command, a write command, a read command, a self-refresh entry command, a self-refresh exit command, an auto-refresh command, a mode setting command, etc.

The memory device 1100 may store the data DQ. The memory device 1100 may operate in response to control by the memory controller 1200. The memory device 1100 may include a memory cell array in which a plurality of memory cells for storing data DQ are arranged in an array type. The memory device 1100 may include a DRAM (Dynamic Random Access Memory) having dynamic memory cells requiring refresh. In some embodiments, the memory device 1100 may be a DDR SDRAM (Double Data Rate Synchronous DRAM), LPDDR (Low Power DDR) SDRAM, GDDR (Graphics DDR) SDRAM, or RDRAM (Rambus DRAM).

The memory device 1100 may receive the command/address signal C/A from the memory controller 1200 and access a region selected by the address within the memory cell array. That is, the memory device 1100 may perform an operation indicated by the command for the region selected by the address. For example, the memory device 1100 may write the data DQ to the selected region in response to a write command, or read the data DQ from the selected region in response to a read command. The memory device 1100 may periodically activate an internal refresh signal during a self-refresh operation period defined by a self-refresh entry command and a self-refresh exit command, to thereby perform a self-refresh operation. Alternatively, the memory device 1100 may activate the internal refresh signal whenever an auto-refresh command is input, to thereby perform an auto-refresh operation accordingly.

The memory device 1100 may correspond to the memory device 100 shown in FIG. 2 or the memory device 400 shown in FIG. 10. That is, the memory device 1100 may be configured to apply the FGR mode during a self-refresh operation regardless of the mode setting.

In one embodiment, the memory device 1100 may include a refresh control circuit configured to generate an internal refresh signal based on a self-refresh section signal; a locking control circuit configured to generate the self-refresh section signal according to a self-refresh entry command and a self-refresh exit command, and generate a locking start signal according to the self-refresh section signal and the internal refresh signal; and a clock generation circuit configured to generate an internal clock by delaying and fixing an external clock in response to the locking start signal. Accordingly, the memory device 1100 according to an embodiment of the present disclosure may suppress the peak current and prevent malfunction in the locking operation by adjusting the locking operation start timing not to overlap with the refresh operation due to the internal refresh signal generated just before exiting from the self-refresh mode.

In another embodiment, the memory device 1100 may include a refresh control circuit configured to generate an internal refresh signal based on a self-refresh section signal; a locking control circuit configured to generate the self-refresh section signal according to a self-refresh entry command and a self-refresh exit command, generate a first extension section signal having a variable activation period depending on the internal refresh signal, and a second extension section signal having a preset activation period, based on the self-refresh section signal, and generate a locking start signal by selecting one of the first extension section signal and the second extension section signal based on operation speed information; and a clock generation circuit configured to generate an internal clock by delaying and fixing an external clock in response to the locking start signal. Accordingly, the memory device 1100 according to an embodiment of the present disclosure may ensure both stability in high-speed operation and efficiency in low-speed operation by adjusting the locking operation start timing according to the operating speed not to overlap with the refresh operation due to the internal refresh signal generated just before exiting from the self-refresh mode.

Various embodiments of the present disclosure have been described in the drawings and specification. Although specific terminologies are used here, the terminologies are only to describe the embodiments of the present disclosure. Therefore, the embodiments of the present disclosure are not restricted to the above-described embodiments and many variations are possible within the spirit and scope of the present disclosure. It should be apparent to those skilled in the art that various modifications can be made based on the technological scope of the present disclosure in addition to the embodiments disclosed herein. The embodiments may be combined to form additional embodiments.

It should be noted that although the technical spirit of the disclosure has been described in connection with embodiments thereof, this is merely for description purposes and should not be interpreted as limiting. It should be appreciated by one of ordinary skill in the art that various changes may be made thereto without departing from the technical spirit of the present disclosure and the following claims.

For example, for the logic gates and transistors provided as examples in the above-described embodiments, different positions and types may be implemented depending on the polarity of the input signal.

What is claimed is:

1. A memory device comprising:
a refresh control circuit configured to generate an internal refresh signal based on a self-refresh section signal;
a locking control circuit configured to generate the self-refresh section signal according to a self-refresh entry command and a self-refresh exit command, and generate a locking start signal according to the self-refresh section signal and the internal refresh signal; and
a clock generation circuit configured to generate an internal clock by delaying and fixing an external clock in response to the locking start signal.

2. The memory device of claim 1, further comprising:
a mode setting circuit configured to read configuration data in response to a mode setting command; and
a mode control circuit configured to output a first mode signal or a second mode signal based on the configuration data, and output the second mode signal regardless of the configuration data when the self-refresh section signal is activated.

3. The memory device of claim 2, wherein the refresh control circuit is configured to adjust a number, a pulse width, or both of the internal refresh signal according to the first mode signal and the second mode signal.

4. The memory device of claim 1, wherein the locking control circuit is configured to:
activate the locking start signal according to a falling edge of the internal refresh signal when the internal refresh signal is activated at deactivation of the self-refresh section signal,
activate the locking start signal according to the deactivation of the self-refresh section signal when the internal refresh signal is inactivated at the deactivation of the self-refresh section signal.

5. The memory device of claim 1,
wherein the locking control circuit includes:
a self-refresh control circuit configured to generate the self-refresh section signal according to the self-refresh entry command and the self-refresh exit command, and generate a first extension section signal and a second extension section signal according to the self-refresh section signal; and
a start control circuit configured to output the locking start signal by selecting one of the first extension section signal and the second extension section signal, and
wherein the first extension section signal has a variable activation period depending on the internal refresh signal, and the second extension section signal has a preset activation period.

6. The memory device of claim 5, wherein the self-refresh control circuit includes:
a first signal generator configured to generate the self-refresh section signal, which is activated by the self-refresh entry command and deactivated by the self-refresh exit command;
a second signal generator configured to generate the first extension section signal, which is activated when the self-refresh section signal is activated and deactivated when the self-refresh section signal is deactivated, the first extension section signal having an extended activation period that is variable depending on whether the internal refresh signal is activated at deactivation of the self-refresh section signal; and
a third signal generator configured to generate the second extension section signal, which is activated by the self-refresh entry command and deactivated by a delayed signal generated by delaying the self-refresh exit command by a preset delay time.

7. The memory device of claim 6, wherein the second signal generator includes:
an inverter configured to invert the self-refresh section signal;
a first NAND gate and a second NAND gate cross-coupled at their input and output terminals, the first NAND gate receiving an output of the inverter and the second NAND gate receiving the internal refresh signal; and
a buffer configured to buffer an output of the first NAND gate to output the first extension section signal.

8. The memory device of claim 6, wherein the third signal generator includes:
a delay circuit configured to delay the self-refresh exit command by the preset delay time to generate the delayed signal; and
an SR latch configured to generate the second extension section signal activated by the self-refresh entry command and deactivated by the delayed signal.

9. The memory device of claim 6, wherein the preset delay time is shorter than a pulse width of the internal refresh signal.

10. The memory device of claim 5, wherein the start control circuit includes:
a first multiplexer configured to output a pre-extension section signal by selecting one of the first extension section signal and the second extension section signal based on a first test mode signal; and
a second multiplexer configured to output the locking start signal by selecting one of the self-refresh section signal and the pre-extension section signal based on a second test mode signal.

11. A memory device comprising:
a refresh control circuit configured to generate an internal refresh signal based on a self-refresh section signal;
a locking control circuit configured to generate the self-refresh section signal according to a self-refresh entry command and a self-refresh exit command, generate a first extension section signal and a second extension section signal based on the self-refresh section signal, and generate a locking start signal by selecting one of the first extension section signal and the second extension section signal based on operation speed information, the first extension section signal having a variable activation period depending on the internal refresh signal and the second extension section signal having a preset activation period; and
a clock generation circuit configured to generate an internal clock by delaying and fixing an external clock in response to the locking start signal.

12. The memory device of claim 11, wherein the refresh control circuit is configured to generate the internal refresh signal based on the self-refresh section signal and adjust a number, a pulse width, or both of the internal refresh signal based on a mode signal indicating a Fine Granularity Refresh (FGR) mode.

13. The memory device of claim 12, wherein the mode signal indicates the FGR mode during an activation period of the self-refresh section signal.

14. The memory device of claim 12,
wherein the preset activation period includes the activation period of the self-refresh section signal and a preset delay time, and
wherein the preset delay time is shorter than a pulse width of the internal refresh signal.

15. The memory device of claim 11, wherein the locking control circuit includes:
a self-refresh control circuit configured to generate the self-refresh section signal according to the self-refresh entry command and the self-refresh exit command, and generate the first extension section signal and the second extension section signal according to the self-refresh section signal; and
a start control circuit configured to output the locking start signal by selecting one of the first extension section signal and the second extension section signal based on the operation speed information.

16. The memory device of claim 15, wherein the start control circuit includes:
a selection control circuit configured to set a plurality of speed signals based on the operation speed information and output a selection signal by selecting one of the speed signals in response to a first test mode signal;
a first multiplexer configured to output a pre-extension section signal by selecting one of the first extension section signal and the second extension section signal according to the selection signal; and
a second multiplexer configured to output the locking start signal by selecting one of the pre-extension section signal and the self-refresh section signal in response to a second test mode signal.

17. The memory device of claim 16, wherein the selection control circuit includes:
a speed setting circuit configured to generate the speed signals having logic levels based on the operation speed information; and
a third multiplexer configured to output the selection signal by selecting one of the speed signals in response to the first test mode signal.

18. An operating method of a memory device, the operating method comprising:
generating at least one speed signal having a logic level based on operation speed information;
generating a self-refresh section signal activated by a self-refresh entry command and deactivated by a self-refresh exit command;
generating an internal refresh signal during an activation period of the self-refresh section signal;
generating a first extension section signal with a variable activation period depending on the internal refresh signal and a second extension section signal with a preset activation period;
generating a locking start signal by selecting one of the first extension section signal and the second extension section signal according to the speed signal; and
generating an internal clock by delaying and fixing an external clock in response to the locking start signal.

19. The operating method of claim 18, wherein generating the internal refresh signal includes:
adjusting a number, a pulse width, or both of the internal refresh signal based on a mode signal indicating a Fine Granularity Refresh (FGR) mode.

20. The operating method of claim 19,
wherein the preset activation period includes the activation period of the self-refresh section signal and a preset delay time, and
wherein the preset delay time is shorter than a pulse width of the internal refresh signal.

21. The operating method of claim 18, wherein generating the locking start signal includes:
selecting the first extension section signal when the speed signal has a first logic level indicating a speed higher than a reference speed; and
selecting the second extension section signal when the speed signal has a second logic level indicating a speed lower than the reference speed.
